(19) United States
(12) Patent Application Publication
(10) Pub. No.: US 2023/0127991 A1
(43) Pub. Date: Apr. 27, 2023

(54) LIGHT SCANNER PACKAGE AND METHOD FOR MANUFACTURING SAME

(71) Applicants: WEMEMS CO.,LTD., Gwangju (KR); GWANGJU INSTITUTE OF SCIENCE AND TECHNOLOGY, Gwangju (KR)

(72) Inventors: Jonghyun LEE, Gwangju (KR); Seunghwan MOON, Gwangju (KR); Jinhong CHOI, Gwangju (KR); Kyoungwoo JO, Gwangju (KR)

(21) Appl. No.: 17/914,757

(22) PCT Filed: Mar. 26, 2021
(86) PCT No.: PCT/KR2021/003801

§ 371 Date: Sep. 26, 2022

(30) Foreign Application Priority Data
Mar. 26, 2020 (KR) 10-2020-0036837
Mar. 26, 2021 (KR) 10-2021-0039815

(51) Int. Cl. B81B 7/02; G02B 26/10; B81C 1/00

(52) U.S. Cl. CPC B81B 7/02; G02B 26/10; B81C 1/00198; B81B 2201/042; B81B 2203/0163; B81B 2203/033; B81B 2203/04; B81B 2207/11; B81B 2203/058; B81C 2201/0118; B81C 2201/0133; B81C 2201/0132; B81C 2203/036; B81C 2203/031

(57) ABSTRACT

The present disclosure relates to an optical scanner package comprising a scanner element, a lower substrate having an inner space, and a semi-spherical transmissive window. The semi-spherical transmissive window has different inclinations in an incident position thereof and in an emission position thereof, and interference caused by sub-reflection can thus be reduced. Since the incident angle α and the maximum emission angle β are small, anti-reflection coating design is easy, and light loss can be reduced. There is an advantage in that, even when the optical scanning angle (OSA) γ of a laser is large, the maximum emission angle β is small, and emitted laser light thus has a small change in characteristics. In addition, since there are curvatures on both sides of two axes, there is little restriction regarding the incident direction even in the case of two-axis driving.

### CROSS-REFERENCE TO RELATED APPLICATIONS

The present application is a national stage filing under 35 U.S.C § 371 of PCT application number PCT/KR2021/003801 filed on Mar. 26, 2021 which is based on and claims priorities to Korean Patent Application No. 10-2020-0036837 filed on Mar. 26, 2020, and Korean Patent Application No. 10-2021-0039815 filed on Mar. 26, 2021, in the Korean Intellectual Property Office, which are incorporated herein by reference in their entireties.

### TECHNICAL FIELD

The present disclosure relates to an optical scanner package and a method for manufacturing the same, and more particularly, to an optical scanner package including transmissive window capable of minimizing interference between a sub-reflected light reflected from the transmissive window and a main reflected light reflected from a mirror, and a method for manufacturing the same.

### BACKGROUND ART

It is necessary to illuminate an image region in small image sensors or displays such as LiDAR (Light Detection And Ranging) and pico-projectors. In this connection, when the corresponding region is scanned with a laser light source, the resolution and contrast of the image are excellent. For scanning, a Micro Electro Mechanical System (MEMS) scanner with characteristics of small size, high speed, and low power is in the spotlight. This MEMS scanner element consists of a mirror 25, a spring 22, a driver 30, and a fixed body 21, and a base layer 40 may be added to a lower portion (see FIG. 1). The laser scan angle (twice of the mirror driving angle) is directly related to an image size, and in order to increase the driving angle of the mirror under the same voltage conditions, the air damping needs to be reduced. In order to enlarge the driving angle of the mirror, it may be driven at a resonant frequency. Since this region is a damping-controlled region, the driving angle increases as the degree of vacuum increases. In order to maintain the vacuum, a transmissive window (window cover) for sealing (hermetic sealing) is required. In this connection, the transmittance of a laser passing region needs to be high to reduce noise interference and energy loss due to reflection.

The MEMS mirror scanner is used for high-speed scanning of a laser, which is essential for image measurement, in LiDAR, a core sensor for autonomous driving (see FIG. 2).

Referring to FIG. 3, anti-reflection coating (ARC) may be applied to increase the transmittance of a transmissive window 50, but perfect ARC is impossible. Accordingly, the main reflection (reference numeral 71 in an initial position of the mirror, and reference numerals 71a and 71b when scanned) occurs in which most of incident light 70 is reflected from the mirror 25 together with sub-reflection (see reference numeral 72) which is reflected from the surface of the transmissive window. Since the thickness of the transmissive window is equal or less than 1 mm, the trajectory change caused thereby is omitted.

When the transmissive window is horizontal and the incident light and the scan direction θ_{y} are in one plane (x-z plane in FIG. 3), a sub-reflected light 72 overlaps main reflected light 71a reflected by the mirror 25 and interferes with a laser scan region. Although the sub-reflection ratio is usually only a few percent, since the position is fixed, the intensity is much higher than that of the fast-moving main reflection in most cases. Since this sub-reflected light acts as a noise signal while being reflected from other objects not in a measurement position, it reduces the quality of an image or it damages the cornea when a person is in an image region resulting in an eye safety issue.

In order to solve the problem mentioned before, as shown in FIG. 4, instead of maintaining the transmissive window 50 horizontally, a method of inclining a mirror 25 by φ has been proposed in a related art. Herein, the scanner element needs to be inclined sufficiently so that the sub-reflected light 72 is sufficiently angularly separated from an upper boundary (reference numeral 71a) of the main reflected light 71. Since the laser becomes unstable when the sub-reflected light 72 returns to the laser, it also needs to be angularly separated from the incident light 70. In order to incline the scanner element as described above, a substrate having a protrusion structure (pillar) is additionally required.

Instead of inclining the scanner element, as shown in FIG. 5, even when the flat-panel transmissive window 50 is inclined by φ, the benefit of the sub-reflected light 72 moving away from the scan region may be obtained. However, when the scan angle γ is increased, the maximum emission angle β increases, making it difficult to design the ARC, which may cause light loss. As shown in FIG. 6, when the incident plane (x-z plane) and the driving plane θₓ are perpendicular to each other, the sub-reflected light 72 has no relation to the scan angle γ of the main reflected light 71, so the separation from the sub-reflected light 72 becomes easier.

As a technique for addressing the problem associated with the sub-reflected light in the aforementioned manner, a scanner packaging structure as shown in FIG. 7 is presented in the related art document US Patent Application Publication No. US2006/0176539.

However, when the transmissive window is inclined only in one axis as shown in FIGS. 5 to 7, there is a limitation that light needs to be incident only in the inclined direction. In order to solve this problem, it is preferable that the inclination of the transmissive window be formed in both x and y axis directions.

### RELATED ART DOCUMENT

(Patent Document 1) US Patent Application Publication No. US2006/0176539, Aug. 10, 2006

### DISCLOSURE

### Technical Problem

The present disclosure has been devised to solve the problem associated with sub-reflection of the aforementioned related art, and is designed to provide a MEMS mirror scanner having a transmissive window structure capable of reducing interference caused by sub-reflection and allowing for easy anti-reflection coating design to reduce light loss, and a method for manufacturing the same in air or vacuum.

### Technical Solution

According to an embodiment of the present disclosure, there is provided an optical scanner package including: a MEMS scanner element including a mirror, a spring, a driver, and a fixed body; a lower substrate positioned at an upper portion or a lower portion of the MEMS scanner element and supporting the MEMS scanner element in a form bonded to the MEMS scanner element; and a transmissive window having a shell shape corresponding to a portion of a semi-sphere or ellipsoid in outward appearance, and having a bonding surface continuously connected to the lower portion, wherein the transmissive window may have a structure having curvatures in two axes.

In addition, the optical scanner package according to an embodiment of the present disclosure includes a lens or an optical element capable of changing a cross-sectional profile of a laser beam in a partial region of the transmissive window through which incident light and emission light pass. The lens may be formed integrally with the transmissive window.

In addition, in the optical scanner package according to an embodiment of the present disclosure, the transmissive window may have a portion of a shallow semi-sphere or a portion of an ellipsoid in which a ratio of height (h) to lower diameter (D) of the transmissive window is in the range of 0.3 to 0.4.

In addition, in the optical scanner package according to an embodiment of the present disclosure, the lower substrate may be made of a glass material, and an inner space may be formed at an upper portion of the lower substrate.

In addition, in the optical scanner package according to an embodiment of the present disclosure, the optical scanner package includes a via metal filled in an up-down direction of the lower substrate.

In addition, in the optical scanner package according to an embodiment of the present disclosure, an opaque blocking film may be formed in a region excluding incident light and emission light regions in the transmissive window.

In addition, the optical scanner package according to an embodiment of the present disclosure may further include: an inner space having an inclined plane angle of 54.7 degrees present on an upper portion of the lower substrate made of a crystalline silicon material; a silicon electrode formed in a trench structure outside a scanner for electrode separation on an upper substrate; an unbroken silicon barrier on an outside of the trench structure; an insulating film formed over the silicon barrier; and two types of metal electrodes formed over the silicon electrode and the insulating film, wherein there may be the transmissive window sealed over a metal electrode of the silicon barrier.

In addition, in the optical scanner package according to an embodiment of the present disclosure, a lower portion of the transmissive window may be bonded with a glass sealing material.

In addition, the optical scanner package according to an embodiment of the present disclosure may include a separate silicon substrate or circuit board for sealing the lower substrate through which the inner space is perforated downward.

In addition, the optical scanner package according to an embodiment of the present disclosure may further include an insulating film filling the trench structure and formed over the barrier; and a metal circuit pattern formed over the insulating film, and the transmissive window sealed over the metal circuit pattern may be included.

In addition, the optical scanner package according to an embodiment of the present disclosure may include: an inner space having cross-sectional shape that becomes wider or keeps same toward a lower portion of the lower substrate; a metal reflective film formed in a lower portion of the mirror; and a circuit board, as a base layer, sealed with a solder in a state where the scanner element and the lower substrate are changed in up-down position.

In addition, the optical scanner package according to an embodiment of the present disclosure may include a silicon substrate having an inner space glued to an electrode of the scanner element with a solder and a barrier with a glass sealing material.

In addition, the optical scanner package according to an embodiment of the present disclosure may include a printed circuit board (PCB) having an inner space in which the electrode of the scanner element is glued by solder and the barrier is glued with the glass sealing material.

In addition, the optical scanner package according to an embodiment of the present disclosure may include a chip carrier replacing the base layer.

In addition, in the optical scanner package according to an embodiment of the present disclosure, a lower portion of the transmissive window may have a square or rectangular shape.

In addition, in the optical scanner package according to an embodiment of the present disclosure, when an inner shape of the chip carrier is a quadrangle, a metal substrate having a large circular hole opened in a center portion may be additionally used.

In addition, in the optical scanner package according to an embodiment of the present disclosure, the blocking film formed on the transmissive window may be an anti-reflection coating layer having an optical reflectivity of 3% or less in a partial range of a wavelength of 300 to 600 nm in at least a partial region of an inner surface and an outer surface of the transmissive window.

In addition, in the optical scanner package according to an embodiment of the present disclosure, the transmissive window may be made of a glass material having thickness of 0.2 to 0.8 mm, and a lower bonding surface portion of the transmissive window may have thickness of 0.4 to 1.6 mm.

In addition, in the optical scanner package according to an embodiment of the present disclosure, the transmissive window, the MEMS scanner element, and the base layer may form a sealed structure through bonding, and the sealed internal pressure may be in a vacuum state of 10⁻¹ to 10⁻⁴ atmospheric pressure.

In addition, a method for manufacturing an optical scanner package according to an embodiment of the present disclosure may include: forming an inner space (cavity) on a glass wafer using wet etching (a1); forming a via-hole on the glass wafer using DRIE or sand blast for electrical connection with a scanner element (a2); forming a metal pattern (seed layer) on a separate Si wafer, aligned with the position of the via-hole (a3); anodic bonding the glass wafer and the Si wafer (a4); filling the via-hole with a conductive material (a5); lowering the height of the top of the Si wafer by CMP processing (a6); forming a metal pattern over a mirror surface, an electric wiring and a pad (a7); forming an element structure and an electrode on the top of the Si wafer by DRIE process (a8); and bonding a semi-spherical or ellipsoidal transmissive window over an external structure (a9).

In addition, in the method for manufacturing the optical scanner package according to an embodiment of the present disclosure, after bonding the transmissive window (a9), the method may further include bonding the transmissive window to a printed circuit board (PCB) using a surface mounting technology.

In addition, a method for manufacturing an optical scanner package according to an embodiment of the present disclosure may include: forming an inner space on a Si wafer using wet etching or DRIE (b1); lowering height of top of the Si wafer by CMP after performing fusion bonding with a separate Si wafer on which an oxide film (BOX: buried oxide) is formed (b2); forming an insulating film in an outermost barrier region of a scanner element (b3); depositing a metal at corresponding positions of a mirror surface, wiring and barrier (b4); forming Si electrode for scanner driving and sensing on an inside of the top of the Si wafer by DRIE process, and simultaneously forming a separate barrier separated by an inner electrode and a trench on an outer edge of a chip (b5); performing wiring between the inner electrode and an outer barrier (b6); and performing sealing by adhering a semi-spherical or ellipsoidal transmissive window in a vacuum atmosphere over an external structure (b7).

In addition, in the method for manufacturing the optical scanner package according to an embodiment of the present disclosure, in the formation of the inner space (b1), instead of the Si wafer, a glass wafer having a cavity may be anodically bonded.

In addition, in the method for manufacturing the optical scanner package according to an embodiment of the present disclosure, in the forming the separate barrier (b5), the barrier may be directly connected to the inner electrode without a trench to prevent electrical floating.

In addition, in the method for manufacturing the optical scanner package according to an embodiment of the present disclosure, in the performing the sealing by adhering the transmissive window (b7), a plurality of holes or dimples may be formed over the metal to strengthen adhesion of the transmissive window.

In addition, a method for manufacturing an optical scanner package according to an embodiment of the present disclosure may include: forming an inner space on a Si wafer using wet etching or DRIE (c1); lowering height of top of the Si wafer by CMP after performing fusion bonding with a separate Si wafer on which an oxide film (BOX: buried oxide) is formed (c2); forming a trench between an inner electrode and a barrier on top of the Si wafer by a DRIE process (c3); filling the trench with an insulator and depositing the insulator to above the barrier (c4); depositing a metal for electrical connection between the inner electrode and the barrier and for formation of a mirror reflective surface (c5); forming a scanner element pattern by DRIE after passivating the metal (c6); and performing sealing by adhering a semi-spherical or ellipsoidal transmissive window in a vacuum atmosphere over an external structure (c7).

In addition, a dielectric thin film may be produced first to form a reflective surface.

In addition, in the method for manufacturing the optical scanner package according to an embodiment of the present disclosure, in the formation of the inner space (c1), a getter material for adsorbing residual gas may be added to an inner space in order to maintain a high vacuum.

In addition, in the method for manufacturing the optical scanner package according to an embodiment of the present disclosure, after the filling and deposition of the insulator (c4), a planarization process may be further performed.

In addition, a method for manufacturing an optical scanner package according to an embodiment of the present disclosure may include: preparing a Si wafer (d1); lowering height of top of the Si wafer by CMP after performing fusion bonding with a separate Si wafer on which an oxide film (BOX: buried oxide) is formed (d2); depositing a metal at a corresponding position of wiring (d3); forming Si electrode for scanner driving and sensing on an inside of the top of the Si wafer by DRIE process, and simultaneously forming a separate barrier separated by an inner electrode and a trench on an outer edge of a chip (d4); forming a through-hole in a (100) Si lower substrate using crystalline wet etching (d5); coating a metal to use an inside of a mirror as a reflective surface of the scanner (d6); forming an insulating film pattern on a separate Si wafer (d7); forming a metal line on the separate Si wafer and then forming an inner space (cavity) in a passivated state (d8); and attaching the separate Si wafer by flip-chip bonding after turning over the Si wafer having a scanner element (d9).

In addition, in the attaching the separate Si wafer (d9) of the method for manufacturing the optical scanner package according to an embodiment of the present disclosure, the inner electrode may be adhered by conductive welding and the outer barrier may be adhered with an insulator.

In addition, the formation of the barrier on the outer edge of the chip (d4) of the method for manufacturing the optical scanner package according to an embodiment of the present disclosure may be performed after the formation of the through-hole (d5).

In addition, the method for manufacturing the optical scanner package according to an embodiment of the present disclosure may include: preparing a Si wafer, and lowering height of top of the Si wafer by CMP after performing fusion bonding with a separate Si wafer on which an oxide film (BOX: buried oxide) is formed (d1); depositing a metal at a corresponding position of wiring and a barrier (d2); forming Si electrode for scanner driving and sensing on an inside of the top of the Si wafer by DRIE process, and simultaneously forming a separate barrier separated by an inner electrode and a trench on an outer edge of a chip (d3); forming a through-hole in a (100) Si lower substrate using crystalline wet etching (d4); coating a metal to use inside of a mirror as a reflective surface of the scanner (d5); bonding a transmissive window to an upper surface of the Si lower substrate (d6); soldering to the top of the Si wafer (d7); and preparing a separate circuit board having a metal line formed thereon and having a cavity therein, and attaching the separate circuit board to the Si wafer having a scanner element by flip-chip bonding after turning over a wafer having a scanner element (d8).

In addition, in the method for manufacturing the optical scanner package according to an embodiment of the present disclosure, the separate circuit board may be one of a PCB, a ceramic circuit board, and an ASIC circuit board.

In addition, in the attaching the separate circuit board (d8) of the method for manufacturing the optical scanner package according to an embodiment of the present disclosure, the inner electrode and the outer barrier may be bonded by conductive welding.

### Advantageous Effects

In an embodiment of the present disclosure configured as above, the semi-spherical transmissive window has different inclinations in an incident position thereof and in an emission position thereof, and interference caused by sub-reflection can thus be reduced.

In addition, since the incident angle (α) and the maximum emission angle (β) are small, anti-reflection coating design is easy, and light loss can be reduced.

In addition, there is an advantage in that, even when the optical scan angle (OSA, γ) of a laser is large, the maximum emission angle (β) is small, and emitted laser light thus has a small change in characteristics.

In addition, since there are curvatures on both sides of two axes, there is little restriction regarding the incident direction even in the case of two-axis driving.

In addition, a semi-spherical (or shallow semi-spherical) transmissive window exhibits a compressive stress with respect to an external pressure when an inside is vacuum, and the stress is not concentrated, so it can be manufactured as thin as 0.4 to 0.8 mm in thickness.

In addition, since the transmissive window originally needs a cavity to make a rotation space of a mirror, the purpose can be achieved by using a semi-spherical window of the same height, so no additional process is required.

### DESCRIPTION OF DRAWINGS

The accompany drawings, which are included to provide a further understanding of the present disclosure and are incorporated on and constitute a part of this specification illustrate embodiments of the present disclosure and together with the description serve to explain the principles of the present disclosure.

FIG. 1 illustrates the structure of a conventional MEMS scanner consisting of a mirror, a spring, a driver, a fixed body, and a lower substrate.

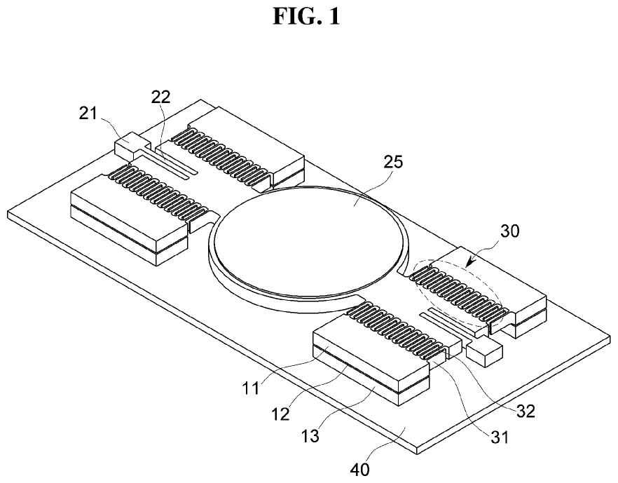

FIG. 2 illustrates an example of a MEMS scanner used in LiDAR which is a core sensor for autonomous driving.

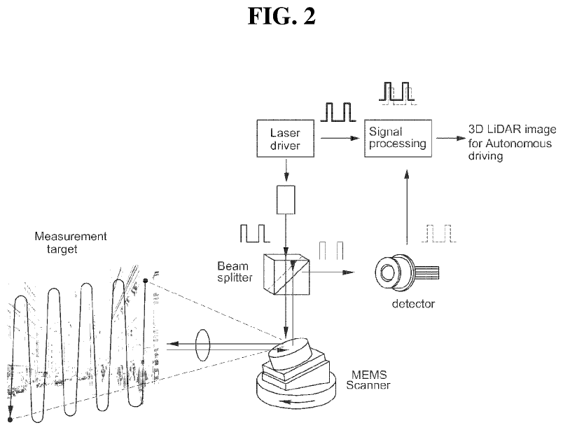

FIG. 3 illustrates a case in which a portion of incident light is reflected from a surface of a transmissive window and enters a scan range.

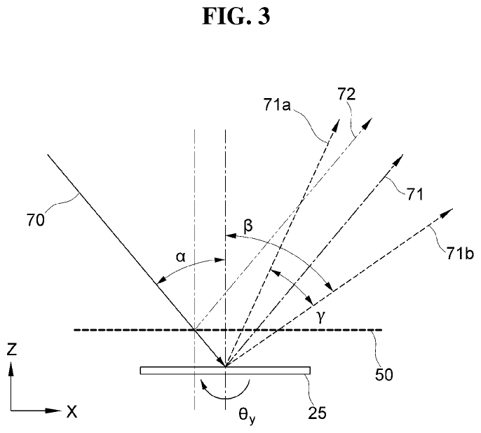

FIG. 4 illustrates a case in which a scanning mirror is inclined in the direction of the angle of incidence.

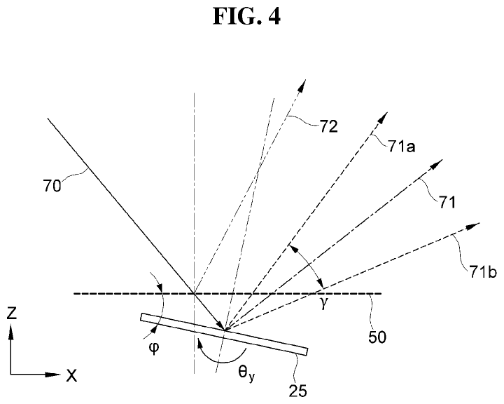

FIG. 5 illustrates a case where the transmissive window is inclined in the direction of an incident angle.

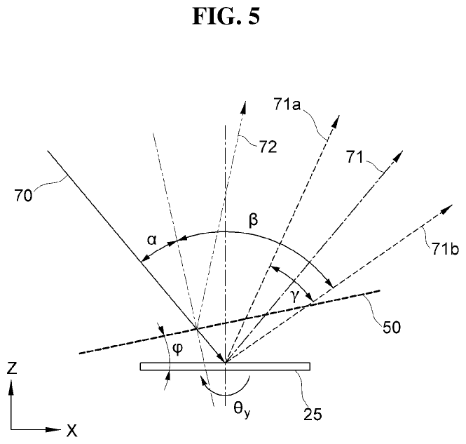

FIG. 6 illustrates that when an incident plane and a driving plane are perpendicular to each other, the sub-reflected light is independent of a scan angle of the main reflected light.

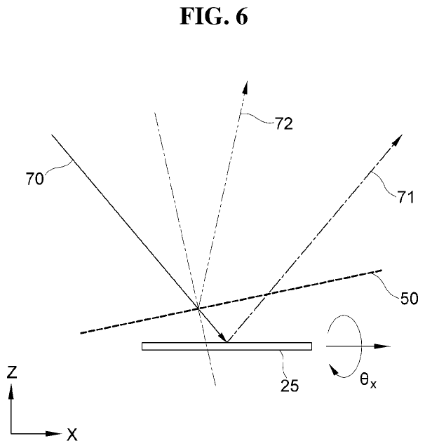

FIG. 7 illustrates the structure of a conventional optical scanner package in which the transmissive window is inclined to address a sub-reflection problem.

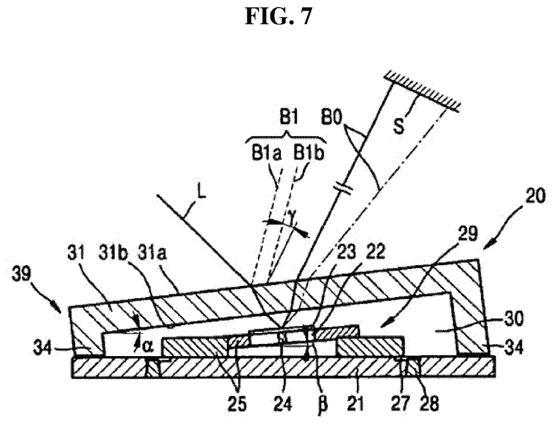

FIG. 8 illustrates the structure of an optical scanner package consisting of a glass lower substrate having an inner space and a semi-spherical transmissive window according to an embodiment of the present disclosure.

FIG. 9 illustrates that when an incident plane and a driving plane are perpendicular to each other, the sub-reflected light is independent of a scan angle of the main reflected light.

FIG. 10 illustrates the structure of an optical scanner package to which a transmissive window combined with a lens or an optical element is applied according to another embodiment of the present disclosure.

FIG. 11 illustrates a manufacturing process of the optical scanner package of FIG. 8.

FIG. 12 illustrates the structure of an optical scanner package in which a silicon lower substrate having an inner space with an inclined surface, and a trench for separating an electrode are formed.

FIG. 13 illustrates a manufacturing process of the optical scanner package of FIG. 12.

FIG. 14 illustrates the structure of an optical scanner package in which a silicon lower substrate having an inner space with a vertical cross section, a base layer for sealing, and a trench for electrode separation are formed.

FIG. 15 illustrates the structure of an optical scanner package in which a silicon lower substrate having a perforated inner space is sealed to a circuit board.

FIG. 16 illustrates a manufacturing process of the optical scanner package of FIG. 14.

FIG. 17 illustrates the structure of an optical scanner package in which an insulating material is filled in a trench.

FIG. 18 illustrates the structure of an optical scanner package in which a planarization process is performed after depositing an insulating film for effective sealing.

FIG. 19 illustrates a manufacturing process of the optical scanner package of FIG. 17.

FIG. 20 illustrates the structure of an optical scanner package sealed using a separate base layer after manufacturing an inclined inner space in a state in which the scanner element is turned over for effective electrical connection.

FIG. 21 illustrates the structure of an optical scanner package with an inner space of a slanted cross section, sealed with a solder using a PCB substrate including the inner space as a base layer in FIG. 20.

FIG. 22 illustrates the structure of an optical scanner package in which an inner space with a vertical cross section is produced on a lower substrate in FIG. 20.

FIG. 23 illustrates the structure of an optical scanner package in which an inner space with a vertical cross section is produced on a lower PCB substrate in FIG. 21.

FIG. 24 illustrates a manufacturing process of the optical scanner package of FIG. 21.

FIG. 25 illustrates the structure of an optical scanner package using a CMOS Si substrate including a driving and sensing circuit instead of a separate Si wafer in FIG. 21.

FIG. 26 illustrates the structure of an optical scanner package having electric wiring electrically connected to a solder pad on a bottom surface through a through-hole of a lower Si circuit board in FIG. 25.

FIG. 27 illustrates a package structure of an optical scanner using a chip carrier.

FIG. 28 illustrates a three-dimensional shape of an optical scanner package according to an embodiment of the present disclosure.

FIG. 29 illustrates a shape of the optical scanner package of FIG. 28 cut along a center line.

### MODE FOR DISCLOSURE

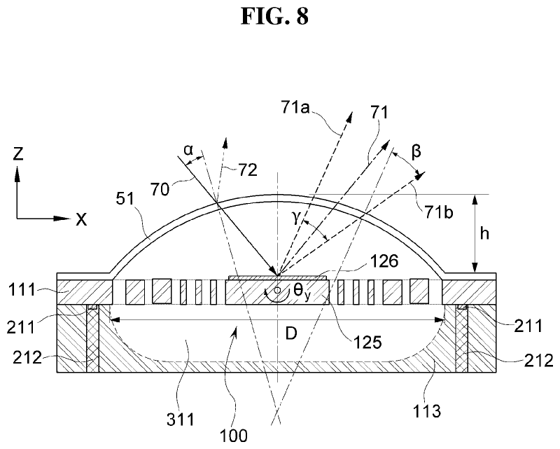

FIG. 8 illustrates the structure of an optical scanner package consisting of a glass lower substrate 113 having an inner space and a semi-spherical transmissive window 51 according to an embodiment of the present disclosure. The structure of the optical scanner package of FIG. 8 includes a scanner element 100, a lower substrate 113 having an inner space 311, and a semi-spherical transmissive window 51. Since the transmissive window 51 has a shallow semi-spherical shape, and thus has different inclinations in an incident position thereof and in an emission position thereof, thereby reducing interference caused by sub-reflection. When a ratio of height (h) to diameter (D) is in the range of 0.3 to 0.4 as a shallow semi-sphere, the amount of sub-reflected light returning to a laser can be reduced, thereby reducing the instability of the laser. In the case of a shallow semi-sphere, the incident angle α has an acute angle rather than a right angle.

In an embodiment of FIG. 8, since the incident angle α and the maximum emission angle β are small, anti-reflection coating design is easy, and light loss can be reduced. Even when the scan angle γ of a laser is large, the maximum emission angle β is small, and emitted laser light thus has a small change in characteristics. In addition, since there are curvatures on both sides of two axes, there is little restriction regarding the incident direction even in the case of two-axis driving. The transmissive window does not need to be a portion of a sphere exactly, and may be a portion of an ellipsoid, such as a rugby ball.

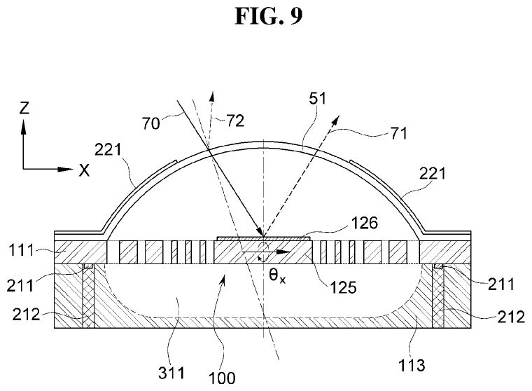

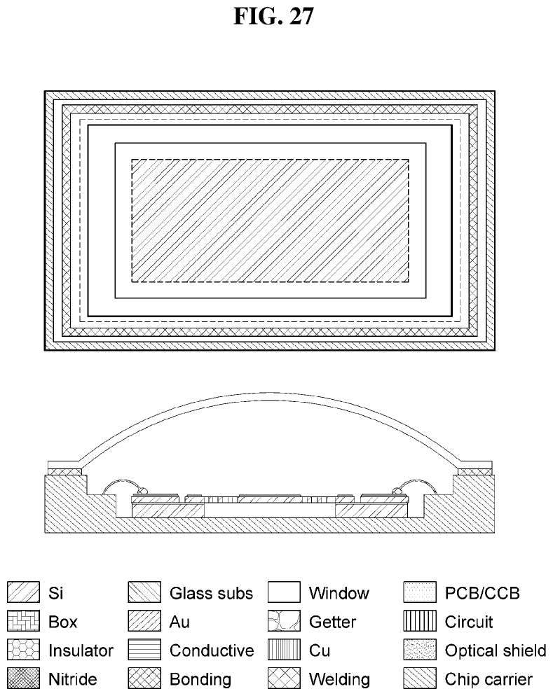

FIG. 9 illustrates that when an incident plane and a driving plane are perpendicular to each other in a scanner of an embodiment of the present disclosure, the sub-reflected light is independent of a scan angle of the main reflected light. In FIG. 9, due to the semi-spherical characteristics, there are curvatures on both directions of x and y axes, which shows that the sub-reflection problem is much less even in a vertical direction of the drive. The form of the transmissive window may have a structure in which there are curvatures on two axes, and the lower portion may have a rectangular shape similar to the chip shape as shown in FIG. 27. Even when the lower portion of the transmissive window has a quadrilateral shape, it may be made to have a spherical structure toward the top, and also in this connection, sub-reflection interference can be effectively avoided. In order to avoid interference with other light, a blocking film 221 of an opaque coating (optical shield) may be formed at a light wavelength used to be opaque except for incident light and emission light regions.

The semi-spherical structure exhibits compressive stress when there is an external pressure, and even the stress is not concentrated. Glass is strong in compressive stress, so it may be safely used even when produced as thin as 0.4 to 0.8 mm thick at 1 atmosphere. In general, the scanner parts are protected by a system housing, so a direct impact is rarely applied. Even in the case of an indirect impact due to an acceleration of several tens of G, the influence on the stress is 1/10 or less of the external pressure, so it may be neglected.

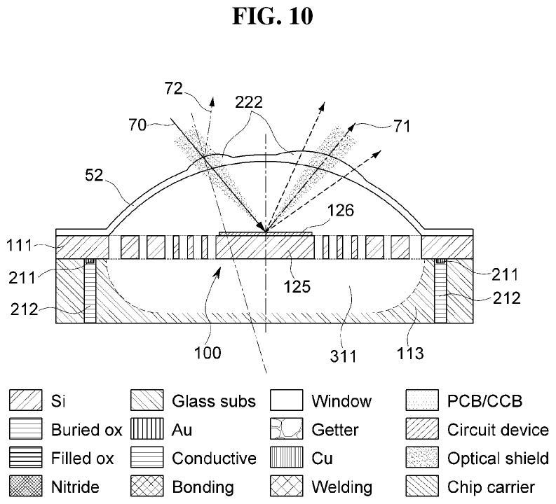

FIG. 10 illustrates the structure of an optical scanner package to which the transmissive window combined with a lens is applied according to another embodiment of the present disclosure. As shown in FIG. 10, when an incident light 70 is collimated, an emission light 71 becomes collimated again when a lens 222, for example, a convex lens, is positioned at the positions of the incident light and the emission light. In this connection, since the cross-sectional area of the beam reaching a mirror 125 is reduced, the size of the mirror may be small, and thus the dynamic deformation of the mirror that occurs when scanning at a high frequency is also reduced.

When the transmissive window has a semi-spherical shape, the incident angle and the emission angle are always perpendicular, so that the cross-sectional profile of the laser beam does not change significantly, but there is a problem that the height of the transmissive window is somewhat increased. In order to lower this height, a portion of an ellipsoid or a shallow semi-spherical shape having a ratio of the height (h) to the lower diameter (D) of the transmissive window in the range of 0.3 to 0.4 may be used. In this connection, a spherical lens or an aspherical optical element for compensating for the shape of the laser beam may be included in a partial region of the transmissive window through which the incident light and the emission light pass so that the change in the cross-sectional profile of the laser beam is minimized.

The driving angle of the mirror is greatly affected by air resistance (air squeeze damping). As the size of the mirror decreases, the air resistance also decreases, so that the driving angle may be increased or the possible driving frequency may be increased. When the driving angle or driving frequency is maintained the same, a portion of the driver (for example, a comb electrode) may be utilized as an integrated sensor for measuring the driving angle. The lens may be produced to be integrated with the transmissive window, and as a result, an optical system such as LiDAR may be produced small by using an integrated lens and integrated sensor. The transmissive window with the integrated lens may be produced by injection molding, and may be combined with an aspherical lens and a concave lens when needed.

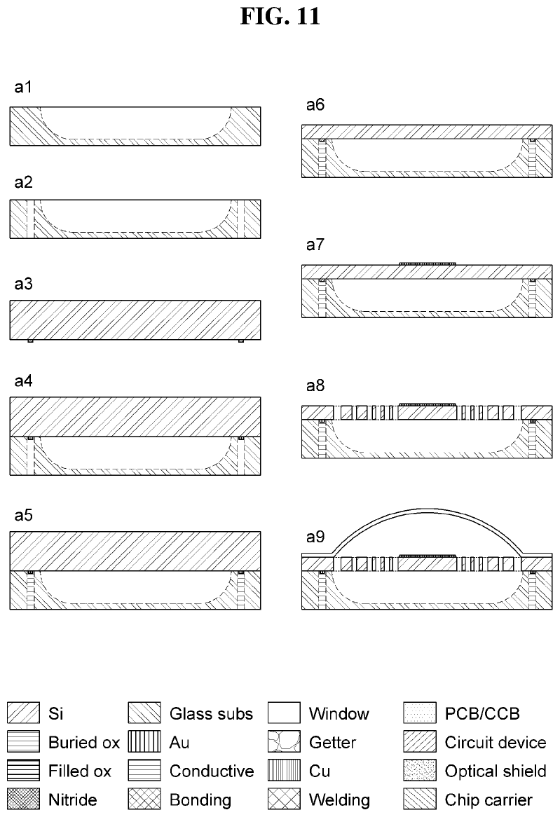

FIG. 11 shows a manufacturing process of the optical scanner package of FIG. 8. A method for manufacturing an optical scanner package, that is, a MEMS mirror scanner, according to an embodiment of the present disclosure will be described with reference to FIG. 11. Here, a process for producing the pattern of a photosensitive film used as an etch mask is a necessary but well-known common process, so it is not shown in the process sequence for manufacturing the optical scanner package of FIG. 8.

a1) An inner space (cavity) 311 is formed on a glass wafer by wet etching.

a2) A via-hole is formed on the glass wafer using DRIE or sand blast for electrical connection with a Si scanner element.

a3) A seed layer 211 of metal pattern is formed on a separate Si wafer, aligned with the position of the via-hole.

a4) The glass wafer and the Si wafer are anodically bonded.

a5) The via-hole is filled with a conductive material. For example, a conductive material may be filled in the via-hole by electroplating. When filled with a metal, it is referred to as a via metal 212.

a6) The height of the top Si is adjusted by CMP. The height of Si is set to approximately 30-90 um.

a7) A metal pattern is made over a mirror surface, an electric wiring and a pad.

a8) An element structure and an electrode are made on the top Si by a DRIE process. In this connection, since there is an inner space, there is no need for a release process.

a9) A semi-spherical transmissive window 52 is bonded over an external structure using vacuum epoxy, frit glass, or anodic bonding.

After process a9) above, it may be adhered to a printed circuit board (PCB) using a surface mounting technology.

In the above manufacturing process, process a5) may be performed after process a9).

Although a via metal process of a glass substrate is added, since surface mounting technology (SMT) may be applied, the process is simple and the product size may be reduced.

When the transmissive glass window is anodically bonded on Si at wafer-level in process a9), the scanner element is protected, so that chip dicing becomes to be easy.

When the bonding process of process a9) is performed in a vacuum, vacuum packaging of the scanner is possible.

Si used in an embodiment of the present disclosure is crystalline Si, which has better reproducibility of properties than conventional polysilicon (poly-Si), and has a yield-stress three times higher than that of polysilicon, resulting in a longer life time.

When the glass transmissive window is independently made and diced, it may be used for chip-level packaging.

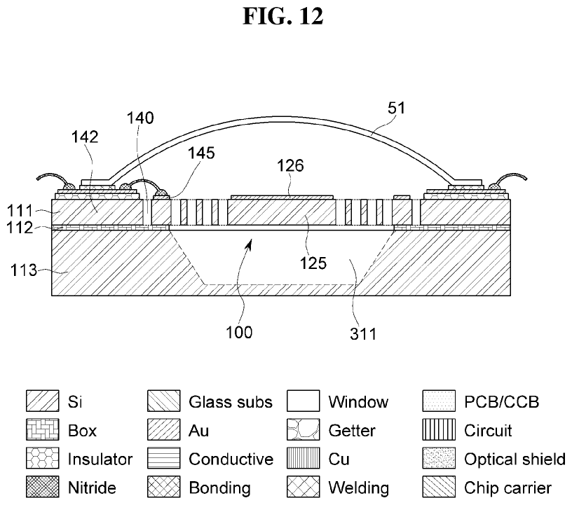

FIG. 12 shows the structure of the optical scanner package in which a silicon lower substrate 113 having the inner space 311 with an inclined surface, and a trench 140 for separating an electrode are formed. FIG. 12 illustrates wiring, which is one embodiment of electric wiring (interconnection) for vacuum packaging. Since the scanner element 100 formed in upper substrate 111 as illustrated in FIG. 12 is made of a single SOL the formation of the scanner element including a trench 140 for electrode separation is very simple.

However, when vacuum packaging is required to increase a driving angle, this trench may be a cause of serious leakage.

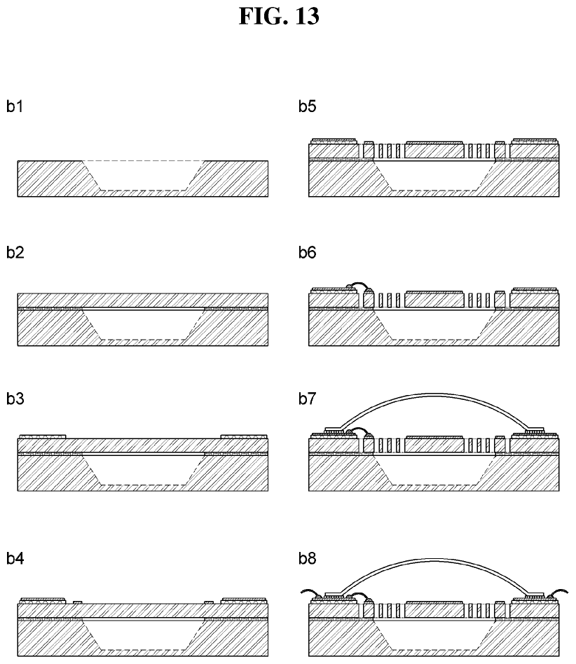

In an embodiment of the present disclosure, trench leakage and wiring issues are solved by the following manufacturing method. The manufacturing method is described with reference to FIGS. 12 and 13 as follows.

b1) An inner space 311 is formed on a Si wafer using wet etching or DRIE.

b2) After performing fusion bonding with a separate Si wafer on which an oxide film (BOX: buried oxide) is formed, the height of top Si is adjusted to approximately 30-90 μm by CMP.

b3) An insulating film is formed in an outermost barrier 142 region of the element.

b4) A metal is deposited at corresponding positions of a mirror surface, wiring and barrier.

b5) Si electrode for scanner driving and sensing is formed on inside of the top Si by a DRIE process, and simultaneously a separate barrier 142 separated by an inner electrode 145 and the trench 140 is formed on an outer edge of a chip.

b6) Wiring is performed between the inner electrode 145 and an outer barrier 142.

b7) Sealing is performed by adhering the transmissive window 51 in a vacuum atmosphere over an external structure using vacuum epoxy or frit glass.

b8) Additional wiring is performed outside the transmissive window 51.

In process b1) above, instead of the Si wafer, a glass wafer having a cavity may be anodically bonded.

The barrier 142 in process b5) may be directly connected to the inner electrode 145 without a trench to prevent floating.

In process b7), a plurality of holes or dimples may be formed over the metal to strengthen the adhesion of the transmissive window.

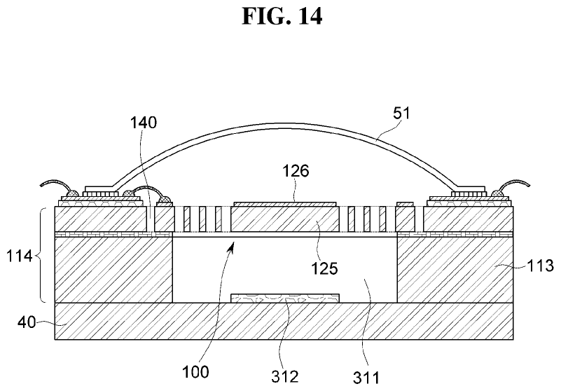

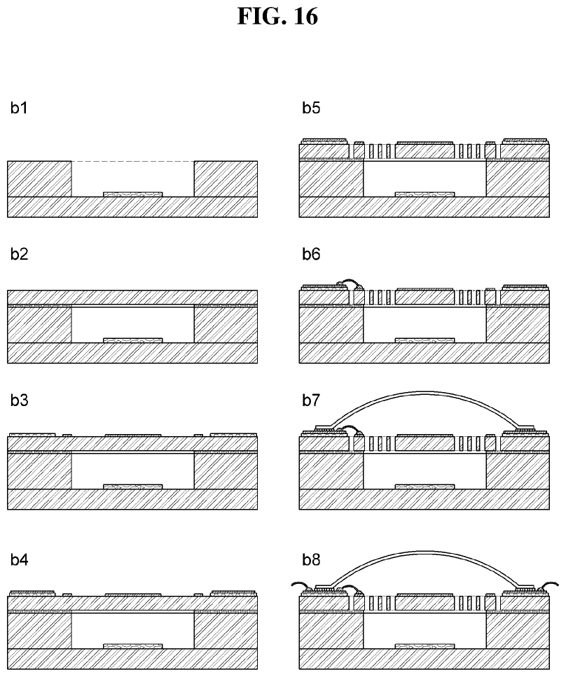

FIG. 14 shows the structure of the optical scanner package in which the silicon lower substrate 113 having the inner space 311 with a vertical cross section, the base layer 40 for sealing, and the trench 140 for electrode separation are formed. FIG. 16 shows a manufacturing process of the optical scanner package of FIG. 14. As illustrated in FIGS. 14 and 16, instead of processes b1) and b2) of FIG. 13, a through-hole is first made in the scanner element 100 and the lower substrate 113 using a SOI wafer 114, and then a separate base layer 40 may be bonded. Herein, when the through-hole is made before the scanner element, the through-hole may be temporarily coated with a polymer to stably produce the scanner element. When the scanner element is first made, a polymer coating may be applied to the scanner element to protect the scanner element before producing the through-hole of the lower substrate.

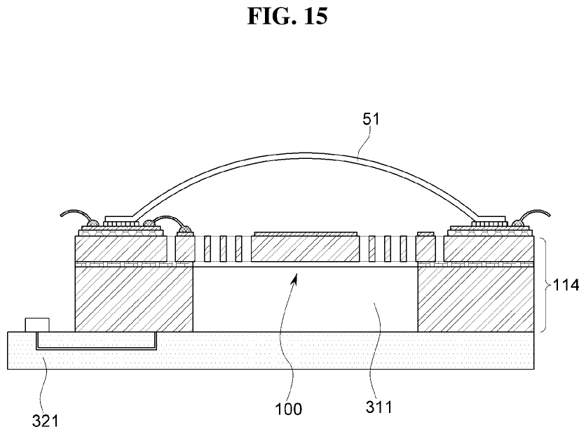

In addition, as illustrated in FIG. 15, a circuit board 321 such as a PCB, a ceramic circuit board (CCB), or an ASIC circuit board may be used instead of the Si or glass substrate at a lowermost portion.

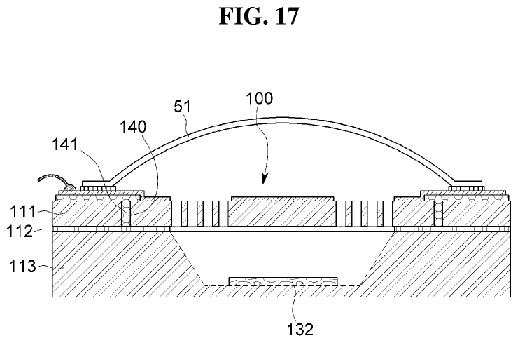

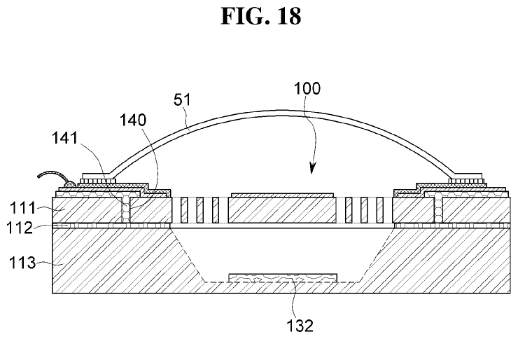

FIGS. 17 and 18 illustrate an example of forming an electric wiring using trench filling as an embodiment of an electric wiring (interconnection) for vacuum packaging.

FIGS. 17 and 18 illustrate a state in which an insulator 141 is filled in the trench 140.

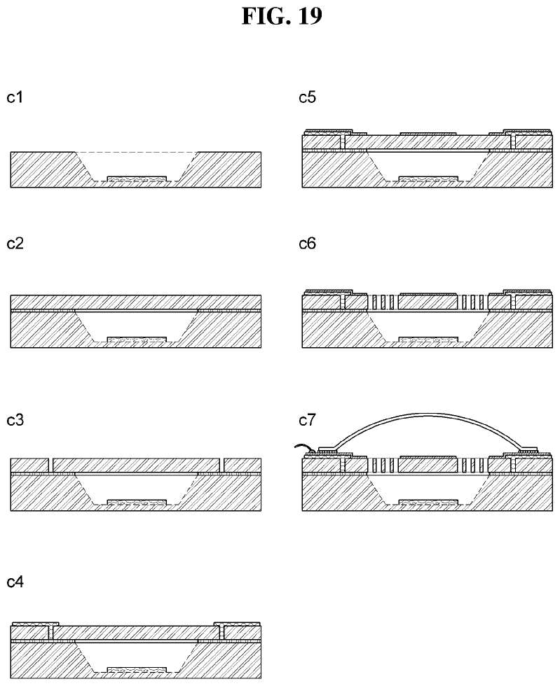

FIG. 19 shows a manufacturing process of the optical scanner package of FIG. 17, and the manufacturing process is as follows.

c1) An inner space is formed on a Si wafer using wet etching or DRIE.

c2) After performing fusion bonding with a separate Si wafer on which an oxide film (BOX: buried oxide) is formed, the height of top Si is adjusted to approximately 30-90 μm by CMP.

c3) A trench is made between an inner electrode and a barrier on the top Si by DRIE process.

c4) The insulator 141 fills the trench 140 and is deposited to above the barrier.

c5) A metal is deposited for electrical connection between the inner electrode and the barrier and for formation of a mirror reflective surface.

c6) After passivating the metal, a scanner element pattern is formed by DRIE.

c7) Sealing is performed by adhering the transmissive window in a vacuum atmosphere over an external structure using vacuum epoxy or frit glass.

In process c1) above, a getter (reference numeral 312 in FIG. 14) material for adsorbing residual gas may be added to an inner space in order to maintain a high vacuum.

In the manufacturing process of FIG. 19, a dielectric thin film may be first produced to form a reflective surface.

When the transmissive window is attached as illustrated in FIG. 18, since the bottom surface is generally smooth, the corresponding lower attachment surface also needs to be smooth without a step. Accordingly, a planarization process can be performed after process c4).

In order to smoothly perform the adhesion of the transmissive window in process c7), a planarization process may be performed after process c4).

As described above, when the structure of FIGS. 17 and 18 is manufactured using insulator trench filling, unnecessary wiring work can be minimized, which is advantageous for mass production.

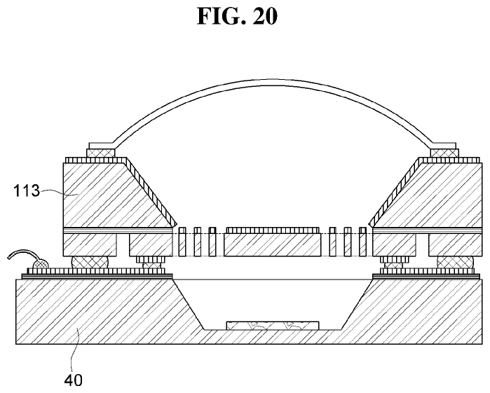

FIGS. 20 to 23 illustrate embodiments of flip-chip bonding on a PCB substrate. The electric wiring process using flip-chip bonding of the optical scanner package of FIG. 20 is as follows.

d1) a Si wafer is prepared.

d2) After performing fusion bonding with a separate Si wafer on which an oxide film (BOX: buried oxide) is formed, the height of top Si is adjusted to approximately 30-90 μm by CMP.

d3) A metal is deposited at a corresponding position of wiring.

d4) Si electrode for scanner driving and sensing is formed on inside of the top Si by a DRIE process, and simultaneously a separate barrier separated by an inner electrode and a trench is formed on an outer edge of a chip.

d5) A through-hole is formed in a (100) Si lower substrate 113 using crystalline wet etching.

d6) The metal is coated to use an inside of a mirror as a reflective surface of the scanner.

d7) An insulating film pattern is formed on a separate Si wafer (see reference numeral 40).

d8) A metal line is formed on the separate Si wafer and then an inner space (cavity) is formed in a passivated state.

d9) After turning over a wafer having a scanner element, the separate Si wafer is attached by flip-chip bonding. In this connection, the inner electrode may be adhered by conductive welding and the outer barrier may be adhered with an insulator.

The process d4) above may be performed after d5).

In the above production process, vacuum packaging is possible on a chip-level or wafer-level level.

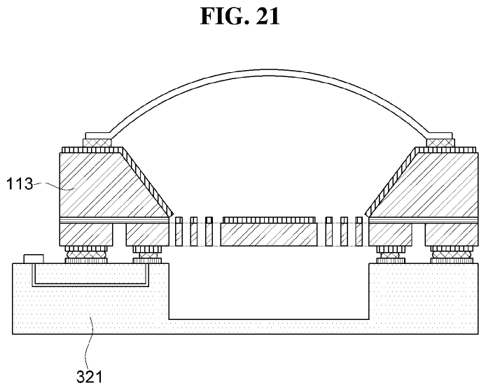

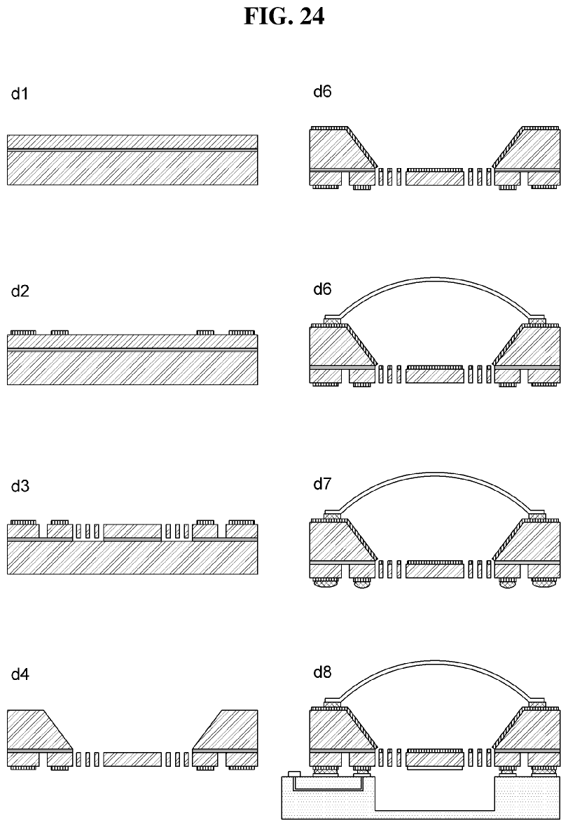

FIG. 21 shows the structure of an optical scanner package sealed with a solder using a PCB substrate including the inner space as a base layer in FIG. 20. FIG. 24 shows a manufacturing process of the optical scanner package of FIG. 21. Referring to FIGS. 21 and 24, instead of a separate Si wafer in process d7), the circuit board 321 such as a PCB having an inner space (cavity) or a ceramic circuit board (CCB) or an ASIC circuit board may be used. In this connection, the top Si structure of the electric wiring is produced to be elongated in a radial direction. This is to minimize the risk of detachment due to temperature change when adhering to a substrate with a different thermal expansion.

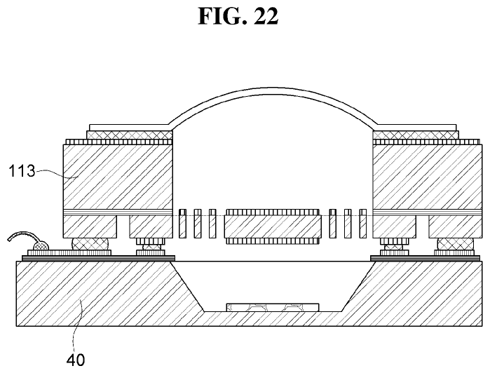

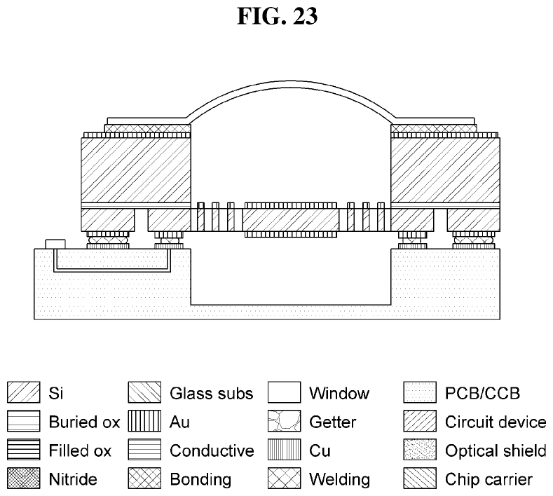

As illustrated in FIGS. 22 and 23, the size of the transmissive window may be reduced by performing vertical processing of the lower substrate 113 using DRIE instead of the crystalline etching of d5) in FIG. 21. In FIGS. 20 to 23, in order to prevent electrical floating of the lower substrate, wiring may be additionally performed.

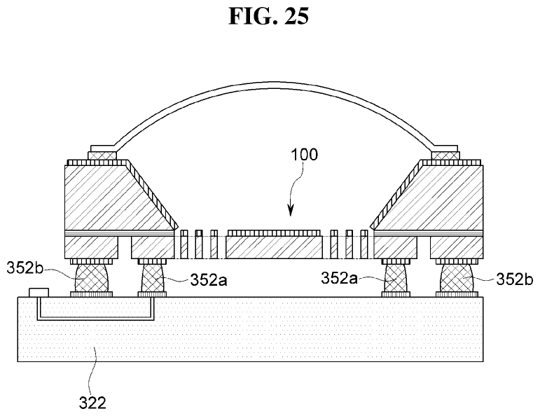

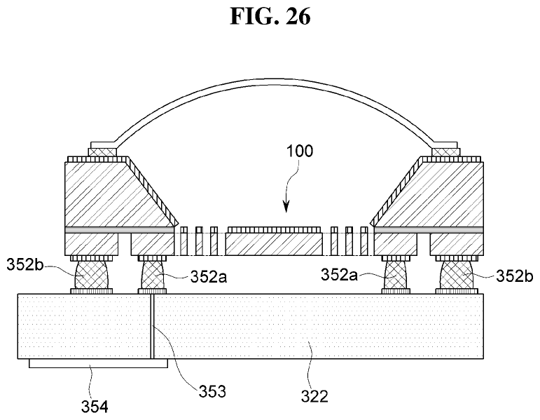

FIG. 25 shows the structure of the optical scanner package using a CMOS Si circuit board 322 including a driving and sensing circuit instead of a separate Si wafer in FIG. 20. In order to secure a space required for driving the mirror, electrical connection and sealing may be performed using solders 352a and 352b such as metal bumps or solder balls having height of 50 to 300 μm. An inner solder 352a is for an electrode for electrical connection, and an outer solder 352b is for sealing. This structure does not require a separate wiring, and direct bonding is possible. FIG. 26 shows the structure of the optical scanner package having electric wiring electrically connected to a solder pad 354 on a bottom surface through a through-hole 353 of the lower CMOS Si circuit board 322 in FIG. 25. Thus, a chip-scale package may be implemented.

FIG. 27 illustrates a package structure using a chip carrier. A semi-spherical transmissive window is used, but vacuum packaging may be performed by directly adhering the same over a chip carrier. An inner shape of the chip carrier may be circular or oval depending on the form of the transmissive window. When the inside shape of the chip carrier is a quadrangle, a metal substrate having a large circular hole opened in a center portion may be used to match the spherical transmissive window. The optical scanner manufactured in this way may be used under normal atmospheric pressure conditions other than vacuum, unless it is hermetic sealing.

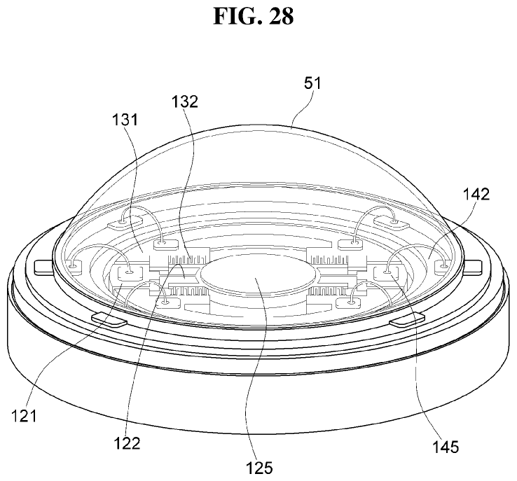

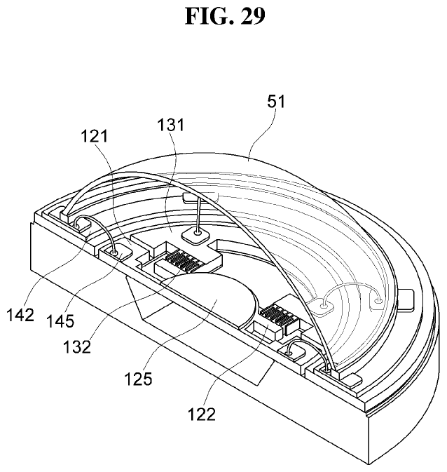

FIG. 28 shows a three-dimensional shape of the optical scanner package according to an embodiment of the present disclosure. FIG. 29 shows the cross-sectional view along a center line. FIGS. 28 and 29 illustrate that a three-dimensional optical scanner package includes a scanner element including a fixed body 121, a spring 122, a mirror 125, a fixed electrode 131, and a driving electrode 132, and the transmissive window 51.

The above description is only illustrative of the technical idea of the present disclosure, and for those skilled in the technical field to which the present disclosure pertains, various modifications, changes, and substitutions will be possible without departing from the essential characteristics of the present disclosure. Accordingly, the present embodiment is not intended to limit the technical idea of the present disclosure, and the scope of the technical idea of the present disclosure is not limited by these embodiments. The scope of protection of the present disclosure should be construed according to the following claims, and all technical ideas within the scope of equivalents thereof should be construed as being included in the scope of right of the present disclosure.

### DESCRIPTION OF REFERENCE NUMERALS

100: SCANNER ELEMENT
11, 111: UPPER SUBSTRATE
12, 112: OXIDE FILM
13, 113: LOWER SUBSTRATE
113A: CIRCUIT BOARD
114: SOI WAFER
21, 121: FIXED BODY
22, 122: SPRING
25, 125: MIRROR
126: METAL REFLECTIVE FILM
31, 131: FIXED ELECTRODE
32, 132: DRIVING ELECTRODE
140: TRENCH
141: INSULATOR
142: BARRIER
145: INNER ELECTRODE
40: BASE LAYER
50, 51, 52: TRANSMISSIVE WINDOW
70: INCIDENT LIGHT
71, 71A, 71B, 171: MAIN REFLECTED LIGHT
72, 172: SUB-REFLECTED LIGHT
211: SEED LAYER
212: VIA METAL
221: BLOCKING FILM
222: LENS
311: INNER SPACE (CAVITY)
312: GETTER
321: CIRCUIT BOARD
322: CMOS SI CIRCUIT BOARD
352, 352A, 352B: SOLDER
353: THROUGH-HOLE
354: SOLDER PAD

1. An optical scanner package including:
a MEMS scanner element including a mirror, a spring, a driver, and a fixed body;
a lower substrate positioned at a lower portion of the MEMS scanner element and supporting the MEMS scanner element in a form bonded to the MEMS scanner element; and
a transmissive window having a shell shape corresponding to a portion of a semi-sphere or ellipsoid in outward appearance, and having a bonding surface continuously connected to the lower portion,
wherein the transmissive window has a structure having curvatures in two axes.

2. The optical scanner package of claim 1, further including a lens or an optical element in a partial region of the transmissive window through which incident light and emission light pass.

3. The optical scanner package of claim 2, wherein the lens is formed integrally with the transmissive window.

4. (canceled)

5. The optical scanner package of claim 1, wherein the lower substrate is made of a glass material, and an inner space is formed at an upper portion of the lower substrate.

6. The optical scanner package of claim 5, further including a via metal filled in an up-down direction of the lower substrate.

7. The optical scanner package of claim 1, wherein an opaque blocking film is formed in a region excluding incident light and emission light regions in the transmissive window.

8. The optical scanner package of claim 1, further including:
an inner space having an inclined plane angle of 54.7 degrees present on an upper portion of the lower substrate made of a crystalline silicon material;
a silicon electrode formed in a trench structure outside a scanner for electrode separation on an upper substrate;
an unbroken silicon barrier on an outside of the trench structure;
an insulating film formed over the silicon barrier; and
two types of metal electrodes formed over the silicon electrode and the insulating film,
wherein there is the transmissive window sealed over a metal electrode of the silicon barrier.

9. (canceled)

10. The optical scanner package of claim 8, further including a separate silicon substrate or circuit board for sealing the lower substrate through which the inner space is perforated downward.

11. The optical scanner package of claim 8, further including:
an insulating film filling the trench structure and formed over the barrier; and
a metal circuit pattern formed over the insulating film,
wherein there is the transmissive window sealed over the metal circuit pattern.

12. The optical scanner package of claim 1, further including:
an inner space having cross-sectional shape that becomes wider or keeps same toward a lower portion of the lower substrate;
a metal reflective film formed in a lower portion of the mirror; and
a circuit board, as a base layer, sealed with a solder in a state where an up-down position of the scanner element and the lower substrate are changed.

13. The optical scanner package of claim 12, further including: a silicon substrate having an inner space glued to an electrode of the scanner element with a solder and a barrier with a glass sealing material.

14. (canceled)

15. The optical scanner package of claim 1, further including a chip carrier attached to an underside of the lower substrate.

16. The optical scanner package of claim 15, wherein the lower portion of the transmissive window has a square or rectangular shape.

17. The optical scanner package of claim 15, wherein, when an inner shape of the chip carrier is a quadrangle, a metal substrate having a large circular hole opened in a center portion is additionally used.

18-20. (canceled)

21. A method for manufacturing an optical scanner package, the method including:
forming a cavity on a glass wafer using wet etching (a1);
forming a via-hole on the glass wafer using DRIE or sand blast for electrical connection with a scanner element (a2);
forming a metal pattern (seed layer) on a separate Si wafer, aligned with the position of the via-hole (a3);
anodic bonding the glass wafer and the Si wafer (a4);
filling the via-hole with a conductive material (a5);
lowering the height of the top of the Si wafer by CMP processing (a6);
forming a metal pattern over a mirror surface, an electric wiring and a pad (a7);
forming an element structure and an electrode on the top of the Si wafer by DRIE process (a8); and
bonding a semi-spherical or ellipsoidal transmissive window over an external structure (a9).

22. (canceled)

23. A method for manufacturing an optical scanner package, the method including:
forming an inner space on a Si wafer using wet etching or DRIE (b1);
lowering height of top of the Si wafer by CMP after performing fusion bonding with a separate Si wafer on which an oxide film (BOX: buried oxide) is formed (b2);
forming an insulating film in an outermost barrier region of a scanner element (b3);
depositing a metal at corresponding positions of a mirror surface, wiring and barrier (b4);
forming Si electrode for scanner driving and sensing on an inside of the top of the Si wafer by DRIE process, and simultaneously forming a separate barrier separated by an inner electrode and a trench on an outer edge of a chip (b5);
performing wiring between the inner electrode and an outer barrier (b6); and
performing sealing by adhering a semi-spherical or ellipsoidal transmissive window in a vacuum atmosphere over an external structure (b7).

24. The method of claim 23, wherein in the formation of the inner space (b1), instead of the Si wafer, a glass wafer having a cavity is anodically bonded.

25. The method of claim 23, wherein in the forming the separate barrier (b5), the barrier is directly connected to the inner electrode without a trench to prevent electrical floating.

26. The method of claim 23, wherein in the performing sealing by adhering the transmissive window (b7), a plurality of holes or dimples are formed over the metal to strengthen adhesion of the transmissive window.

27-32. (canceled)

33. A method for manufacturing an optical scanner package, the method including:
preparing a Si wafer, and lowering height of top of the Si wafer by CMP after performing fusion bonding with a separate Si wafer on which an oxide film (BOX: buried oxide) is formed (d1);
depositing a metal at a corresponding position of wiring and a barrier (d2);
forming Si electrode for scanner driving and sensing on an inside of the top of the Si wafer by DRIE process, and simultaneously forming a separate barrier separated by an inner electrode and a trench on an outer edge of a chip (d3);
forming a through-hole in a (100) Si lower substrate using crystalline wet etching (d4);
coating a metal to use inside of a mirror as a reflective surface of the scanner (d5);
bonding a transmissive window to an upper surface of the Si lower substrate (d6);
soldering to the top of the Si wafer (d7); and
preparing a separate circuit board having a metal line formed thereon and having a cavity therein, and attaching the separate circuit board to the Si wafer having a scanner element by flip-chip bonding after turning over the Si wafer (d8).

34-35. (canceled)
